(19) United States
(12) Patent Application Publication
(10) Pub. No.: US 2008/0303422 A1
(43) Pub. Date: Dec. 11, 2008

(54) Organic Electroluminescent Devices

(75) Inventors: Horst Vestweber, Gilersberg-Winterscheid (DE); Holger Heil, Darmstadt (DE); Esther Breuning, Niedernhausen (DE); Amir Parham, Frankfurt (DE)

Correspondence Address: CONNOLLY BOVE LODGE & HUTZ, LLP, P O BOX 2207, WILMINGTON, DE, 19899, US

(73) Assignee: Merck Patent GmbH, Darmstadt (DE)

(21) Appl. No.: 12/096,423

(22) PCT Filed: Nov. 17, 2006
(86) PCT No.: PCT/EP2006/011027

§ 371 Date: Jun. 6, 2008

(30) Foreign Application Priority Data
Dec. 8, 2005 (DE) 10 2005 058 558.2

(51) Int. Cl. H01L 51/54; H01J 9/02

(52) U.S. Cl. 313/504; 445/24

(57) ABSTRACT

The present invention relates to mixtures of organic materials, to the use of these mixtures in organic electroluminescent devices, and to organic electroluminescent devices containing these mixtures.

The present invention relates to mixtures of organic materials, to the use of these mixtures in organic electroluminescent devices, and to organic electroluminescent devices containing these mixtures.

The general structure of organic electroluminescent devices which are capable of the emission of light in the visible spectral region and contain semiconducting organic compounds is described, for example, in U.S. Pat. No. 4,539,507, U.S. Pat. No. 5,151,629, EP 0676461 and WO 98/27136.

However, these devices still exhibit considerable problems which require urgent improvement for use in high-quality full-colour displays. Thus, the operating lifetime, in particular in the case of blue emission, is still inadequate, meaning that it has hitherto only been possible to achieve simple applications commercially. Further improvements are necessary here for high-quality full-colour displays.

JP 08-239655 describes various styrylamines, each containing at least one stilbene group and at least two arylamino groups, as blue emitters. However, suitable host materials for these compounds are not indicated.

EP 1167488 proposes in general the combination of monostyrylamines, distyrylamines, tristyrylamines or tetrastyrylamines together with certain dianthracene derivatives or with anthracene derivatives which are substituted by condensed aromatic ring systems or by aryl groups having 12 or more carbon atoms. Linear styrylamines are mentioned as preferred emitters. The further developments for these styrylamines have likewise been optimised (for example WO 04/013073, WO 04/016575, WO 04/018587). These styrylamines are amongst the best blue-emitting materials currently on the market. Further improvements to suitable host materials are still desirable for these materials in particular in order further to improve the properties, in particular the lifetime.

WO 05/061656 describes asymmetrically substituted anthracene derivatives as host for linear stilbenamines. These compounds have the significant technical disadvantage that, in contrast to symmetrically substituted compounds, they can only be prepared in a complex manner in a plurality of synthesis steps.

The object of the present invention was therefore to offer improvements in this respect, in particular host materials which, with these styrylamines, result in an improvement in the lifetime.

Surprisingly, it has been found that organic electroluminescent devices which contain a combination of certain styrylamines and 9,10-bis(1-naphthyl)anthracene and derivatives thereof in the emitting layer have significant improvements over the prior art, in particular a significantly improved lifetime. This result is therefore particularly surprising since similar host materials in combination with styrylamines are known from the above-mentioned prior art, but exhibit a worse lifetime. The fact that these host materials in this combination have such an influence on the lifetime of the devices is therefore an unexpected and unforeseeable result. The present invention therefore relates to these material mixtures and to the use thereof in OLEDs.

The invention relates to organic electroluminescent devices containing anode, cathode and at least one organic layer, characterised in that the organic layer comprises the following components:

a) at least one compound of the formula (1)

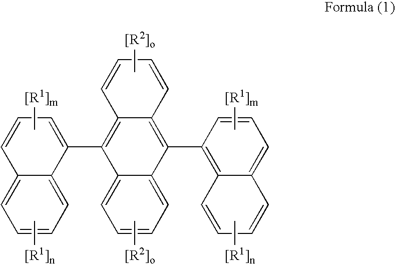

where the following applies to the symbols used:
R¹ is, identically or differently on each occurrence, F, Cl, Br, I, CN, a straight-chain alkyl, alkoxy or thioalkoxy group having 1 to 40 C atoms or a branched or cyclic alkyl, alkoxy or thioalkoxy group having 3 to 40 C atoms, each of which may be substituted by one or more radicals R³, where one or more non-adjacent CH₂ groups may be replaced by —R³C═CR³—, —C≡C—, Si(R³)₂, Ge(R³)₂, Sn(R³)₂, C═O, C═S, C═Se, C═NR², —O—, —S—, —N(R³)— or —CONR³— and where one or more H atoms may be replaced by F, Cl, Br, I, CN or NO₂, or an aralkyl group having 7 to 30 C atoms, which may be substituted by one or more radicals R³, or an aryloxy or heteroaryloxy group having 5 to 24 aromatic ring atoms, which may be substituted by one or more non-aromatic radicals R³; two or more substituents R¹ here may also form a mono- or polycyclic, aliphatic ring system with one another;
R² is on each occurrence, identically or differently, R¹ or an aromatic or heteroaromatic ring system having 5 to 30 aromatic ring atoms, which may be substituted by one or more radicals R³;
R³ is on each occurrence, identically or differently, H or an aliphatic or aromatic hydrocarbon radical having 1 to 20 C atoms; two or more radicals R³ here may also form a mono- or polycyclic, aliphatic or aromatic ring system with one another;
m is, identically or differently on each occurrence, 0, 1, 2 or 3;
n, o are, identically or differently on each occurrence, 0, 1, 2, 3 or 4; and
   b) at least one compound of the formula (2)

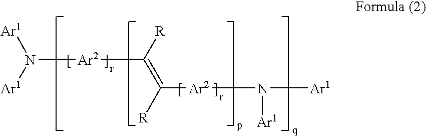

where the following applies to the symbols used:
Ar¹ is, identically or differently on each occurrence, an aromatic or heteroaromatic ring system having 5 to 30 aromatic ring atoms, which may be substituted by one or more radicals R⁴;
Ar² is, identically or differently on each occurrence, an arylene or heteroarylene group having 5 to 20 aromatic ring atoms, which may be substituted by one or more radicals R⁴;
R is, identically or differently on each occurrence, H, F, CN, a straight-chain alkyl group having 1 to 40 C atoms or a branched or cyclic alkyl chain having 3 to 40 C atoms, each of which may be substituted by one or more radicals R⁵, where one or more non-adjacent CH₂ groups which are not bonded directly to the double bond may be replaced by —R⁵C═CR⁵—, —C≡C—, Si(R⁵)₂, Ge(R⁵)₂, Sn(R⁵)₂, C═O, ═S, C═Se, C═NR⁵, —O—, —S—, —N(R⁵)— or —CONR⁵— and where one or more H atoms may be replaced by F, Cl, Br, I, CN or NO₂, or an aryl or heteroaryl group having 5 to aromatic ring atoms, which may in turn be substituted by one or more radicals R⁵ or by a diphenylamino group, where the phenyl groups may be substituted by non-aromatic radicals R;
R⁴ is, identically or differently on each occurrence, H, F, Cl, Br, I, CN, Si(R⁵)₃, N(R⁵)₂, a straight-chain alkyl, alkoxy or thioalkoxy group having 1 to 40 C atoms or a branched or cyclic alkyl, alkoxy or thioalkoxy group having 3 to 40 C atoms, each of which may be substituted by one or more radicals R⁵, where one or more non-adjacent CH₂ groups may be replaced by —R⁵C═CR⁵—, —C≡C—, Si(R⁵)₂, Ge(R⁵)₂, Sn(R⁵)₂, C═O, C═S, C═Se, C═NR⁵, —O—, —S—, —N(R⁵)— or —CONR⁵— and where one or more H atoms may be replaced by F, Cl, Br, I, CN or NO₂, or an aryl or heteroaryl group having 5 to 30 aromatic ring atoms, which may be substituted by one or more non-aromatic radicals R⁵, or an aryloxy or heteroaryloxy group having 5 to 24 aromatic ring atoms, which may be substituted by one or more non-aromatic radicals R⁴; two or more substituents R⁴ here may also form a mono- or polycyclic, aliphatic or aromatic ring system with one another, also on different groups Ar¹ or Ar²;
R⁵ is on each occurrence, identically or differently, H or an aliphatic or aromatic hydrocarbon radical having 1 to 20 0 atoms; two or more radicals R⁵ here may also form a mono- or polycyclic, aliphatic or aromatic ring system with one another;
p, r are, identically or differently on each occurrence, 1, 2 or 3;
q is 1, 2 or 3.

The organic layer is capable of the emission of light and is preferably an emitting layer.

For the purposes of this invention, an aryl group or a heteroaryl group is taken to mean a monovalent aromatic group or a monovalent heteroaromatic group having a common aromatic n-electron system. For the purposes of this invention, an arylene group or heteroarylene group is taken to mean a corresponding divalent group. For the purposes of this invention, this can be a simple homo- or heterocycle, for example benzene, pyridine, thiophene, etc., or it can be a condensed aromatic ring system in which at least two aromatic or heteroaromatic rings, for example benzene rings, “fused” to one another, i.e. are condensed onto one another by anellation, i.e. have at least one common edge and consequently also a common aromatic n-electron system. These aryl or heteroaryl groups may be substituted or unsubstituted; any substituents present may likewise form further ring systems. Thus, for example, systems such as naphthalene, anthracene, phenanthrene, pyrene, etc., are regarded as aryl groups and quinoline, acridine, benzothiophene, carbazole, etc., are regarded as heteroaryl groups for the purposes of this invention, while, for example, biphenyl, fluorene, spirobifluorene, etc., do not represent aryl groups since these involve separate aromatic electron systems.

For the purposes of this invention, an aromatic ring system contains 6 to 30 C atoms in the ring system. For the purposes of this invention, a heteroaromatic ring system contains 2 to 30 C atoms and at least one heteroatom in the ring system, with the proviso that the total number of C atoms and heteroatoms is at least 5. The heteroatoms are preferably selected from N, O and/or S. For the purposes of this invention, an aromatic or heteroaromatic ring system is intended to be taken to mean a system which does not necessarily contain only aryl or heteroaryl groups, but instead in which a plurality of aryl or heteroaryl groups may also be interrupted by a short non-aromatic unit (less than 10% of the atoms other than H, preferably less than 5% of the atoms other than H), such as, for example, an sp³-hybridised C, N or O atom. Thus, for example, systems such as 9,9′-spirobifluorene, 9,9-diarylfluorene, stilbene, triarylamine, diaryl ether, etc., are also intended to be taken to mean aromatic ring systems for the purposes of this invention. Part of the aromatic or heteroaromatic ring system may also be a condensed group here.

For the purposes of the present invention, a C₁- to C₄₀-alkyl group, in which, in addition, individual H atoms or CH₂ groups may be substituted by the above-mentioned groups, is particularly preferably taken to mean the radicals methyl, ethyl, n-propyl, i-propyl, n-butyl, i-butyl, s-butyl, t-butyl, 2-methylbutyl, n-pentyl, s-pentyl, cyclopentyl, n-hexyl, cyclohexyl, n-heptyl, cycloheptyl, n-octyl, cyclooctyl, 2-ethylhexyl, trifluoromethyl, pentafluoroethyl, 2,2,2-trifluoroethyl, ethenyl, propenyl, butenyl, pentenyl, cyclopentenyl, hexenyl, cyclohexenyl, heptenyl, cycloheptenyl, octenyl, cyclooctenyl, ethynyl, propynyl, butynyl, pentynyl, hexynyl or octynyl. A C₁- to C₄₀-alkoxy group is particularly preferably taken to mean methoxy, ethoxy, n-propoxy, i-propoxy, n-butoxy, i-butoxy, s-butoxy, t-butoxy or 2-methylbutoxy. An aromatic or heteroaromatic ring system having 1 to 30 aromatic ring atoms, which may also in each case be substituted by the above-mentioned radicals R¹ or R² and which may be linked to the aromatic or heteroaromatic ring system via any desired positions, are taken to mean, in particular, groups derived from benzene, naphthalene, anthracene, phenanthrene, pyrene, chrysene, perylene, fluoranthene, tetracene, pentacene, benzopyrene, biphenyl, biphenylene, terphenyl, terphenylene, fluorene, spirobifluorene, dihydrophenanthrene, dihydropyrene, tetrahydropyrene, cis- or trans-indenofluorene, furan, benzofuran, isobenzofuran, dibenzofuran, thiophene, benzothiophene, isobenzothiophene, dibenzothiophene, pyrrole, indole, isoindole, carbazole, pyridine, quinoline, isoquinoline, acridine, phenanthridine, benzo-5,6-quinoline, benzo-6,7-quinoline, benzo-7,8-quinoline, phenothiazine, phenoxazine, pyrazole, indazole, imidazole, benzimidazole, naphthimidazole, phenanthrimidazole, pyridimidazole, pyrazinimidazole, quinoxalinimidazole, oxazole, benzoxazole, naphthoxazole, anthroxazole, phenanthroxazole, isoxazole, 1,2-thiazole, 1,3-thiazole, benzothiazole, pyridazine, benzopyridazine, pyrimidine, benzopyrimidine, quinoxaline, pyrazine, phenazine, naphthyridine, azacarbazole, benzocarboline, phenanthroline, 1,2,3-triazole, 1,2,4-triazole, benzotriazole, 1,2,3-oxadiazole, 1,2,4-oxadiazole, 1,2,5-oxadiazole, 1,3,4-oxadiazole, 1,2,3-thiadiazole, 1,2,4-thiadiazole, 1,2,5-thiadiazole, 1,3,4-thiadiazole, 1,3,5-triazine, 1,2,4-triazine, 1,2,3-triazine, tetrazole, 1,2,4,5-tetrazine, 1,2,3,4-tetrazine, 1,2,3,5-tetrazine, purine, pteridine, indolizine and benzothiadiazole.

Preferred embodiments of compounds of the formula (1) are described below.

Preference is furthermore given to compounds of the formula (1) in which the symbol R¹, identically or differently on each occurrence, stands for F, a straight-chain alkyl or alkoxy group having 1 to 6 C atoms or a branched or cyclic alkyl or alkoxy group having 3 to 10 C atoms, where in each case one or more CH₂ groups may be replaced by —R³C═CR³—, Si(R³)₂, —O—, —S— or —N(R³)— and where in each case one or more H atoms may be replaced by F; two or more radicals R¹ here may also form a mono- or polycyclic, aliphatic ring system with one another. Particularly preferred radicals R¹ are selected from the group consisting of F, straight-chain alkyl groups having 1 to 4 C atoms, branched alkyl groups having 3 to 5 C atoms or cyclic alkyl groups having 5 to 10 C atoms, where in each case one or more H atoms may be replaced by F; two or more adjacent radicals R¹ here may also form a mono- or polycyclic, aliphatic ring system with one another.

Preference is furthermore given to compounds of the formula (1) in which the symbol R² stands for an aromatic or heteroaromatic ring system having 5 to 16 aromatic ring atoms, which may be substituted by one or more radicals R³, particularly preferably for an aromatic or heteroaromatic ring system having 6 to 14 aromatic ring atoms, which may be substituted by one or more radicals R³.

Preference is furthermore given to compounds of the formula (1) in which the index m stands for 0, 1 or 2, particularly preferably for 0 or 1. If the index m stands for 1, the substituent R¹ is preferably bonded in the 4-position of the naphthyl.

Preference is furthermore given to compounds of the formula (1) in which the index n stands for 0, 1 or 2, particularly preferably for 0 or 1, very particularly preferably for 0.

Preference is furthermore given to compounds of the formula (1) in which the index o stands for 0, 1 or 2, particularly preferably for 0 or 1, very particularly preferably for 0. If the index o stands for 1, the substituent R¹ is preferably bonded in the 2-position or in the 6-position of the anthracene.

Preference is furthermore given to compounds of the formula (1) whose molecular weight is between 430 and 1200 g/mol, particularly preferably between 430 and 900 g/mol.

The two naphthyl groups may be identically or differently substituted. The two naphthyl groups are preferably identically substituted, so that the compounds of the formula (1) are symmetrical with respect to the substituents on the naphthyl groups.

The compounds of the formula (1) are preferably pure hydrocarbon compounds.

The compounds of the formula (1) exhibit atropisomerism about the naphthyl-anthracene bonds. The invention relates to both OLEDs containing the mixture of the atropisomers and also to OLEDs containing the isolated or enriched atropisomers. This relates both to enantiomers and also to diastereomers. The choice of suitable atropisomers enables, for example, the solubility of the compound and the electro-optical properties to be influenced. This is described, for example, in WO 06/048268.

Examples of preferred compounds of the formula (1) are compounds (H1) to (H20) shown below.

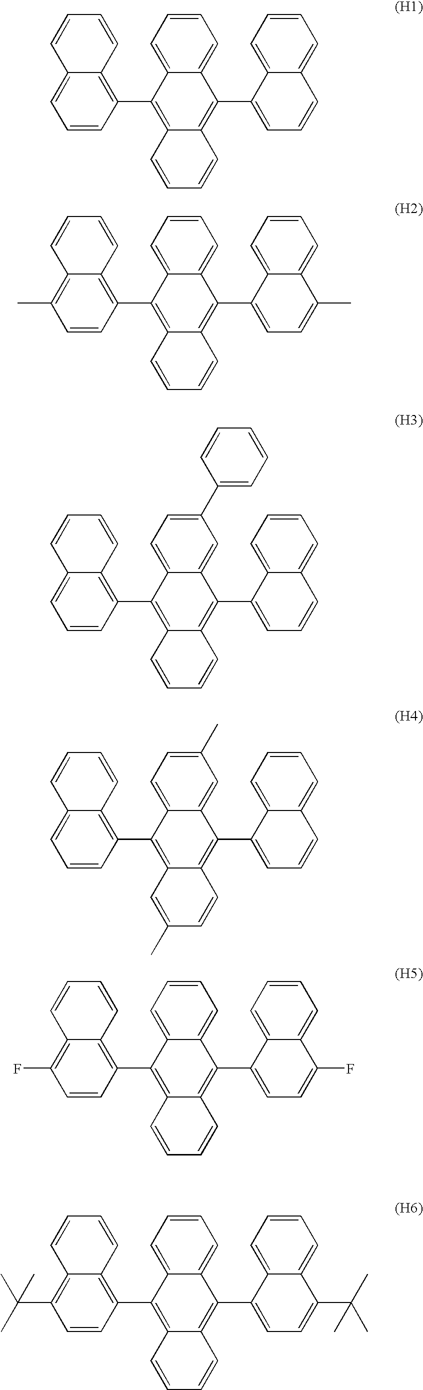

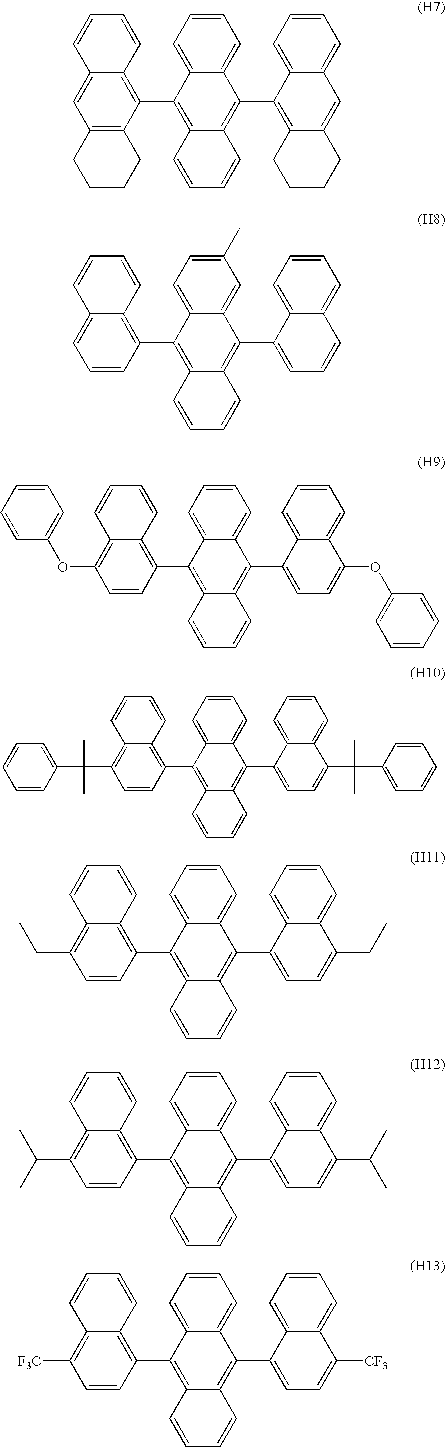

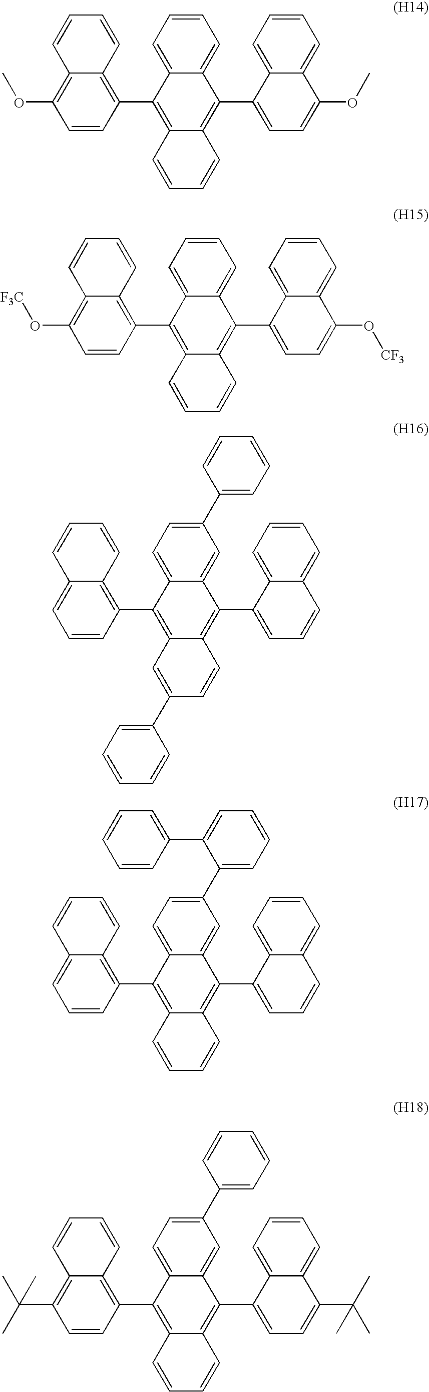

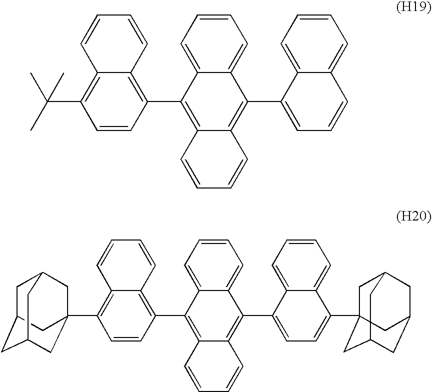

Preferred embodiments of compounds of the formula (2) are described below.

Preference is given to compounds of the formula (2) in which the symbol Ar¹, identically or differently on each occurrence, stands for an aryl, biaryl or heteroaryl group, in particular an aryl or biaryl group, having 6 to 14 C atoms, which may be substituted by one or more radicals R⁴, particularly preferably for a phenyl, biphenyl or naphthyl group, each of which may be substituted by one or more radicals R⁴, very particularly preferably for a phenyl group, which may be substituted by one or more radicals R⁴.

Preference is furthermore given to compounds of the formula (2) in which the symbol Ar², identically or differently on each occurrence, stands for an arylene or heteroarylene group, in particular an arylene group, having 5 to 14 aromatic ring atoms, particularly preferably having 6 to 10 aromatic ring atoms, which may be substituted by one or more radicals R⁴, particularly preferably for a phenylene or naphthylene group, each of which may be substituted by one or more radicals R⁴, in particular for a phenylene group, which may be substituted by one or more radicals R⁴.

Preferred radicals R are hydrogen, a straight-chain alkyl group having 1 to 4 C atoms, a branched or cyclic alkyl group having 3 to 5 C atoms or a phenyl or naphthyl group, each of which may also be substituted by one or more radicals R⁵. The radical R is particularly preferably equal to hydrogen.

Particular preference is thus given to compounds of the following formula (2a), where the phenyl or phenylene groups may also be substituted by one or more radicals R⁴:

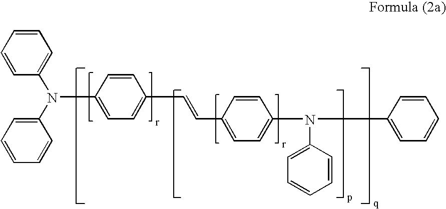

Preferred radicals R⁴ are selected from the group consisting of H, F, straight-chain alkyl or alkoxy groups having 1 to 6 C atoms or branched or cyclic alkyl or alkoxy groups having 3 to 10 C atoms, each of which may be substituted by one or more radicals R⁵ and where in each case one or more CH₂ groups may be replaced by —R⁵C═CR⁵—, Si(R⁵)₂, —O—, —S— or —N(R⁵)— and where in each case one or more H atoms may be replaced by F, or monovalent aryl or heteroaryl groups having 5 to 14 aromatic ring atoms; two or more radicals R⁴ here may also form a ring system with one another. Particularly preferred radicals R⁴ are selected from the group consisting of H, F, straight-chain alkyl groups having 1 to 4 C atoms, branched alkyl groups having 3 to 5 C atoms or Cyclic alkyl groups having 5 to 10 C atoms, each of which may be substituted by one or more radicals R⁵ and where in each case one or more H atoms may be replaced by F, or monovalent aryl or heteroaryl groups having 6 to 10 aromatic ring atoms; two or more radicals R⁴ here may also form a ring system with one another. Very particularly preferred radicals R³ are selected from H, F, methyl, CF₃, ethyl, isopropyl, tert-butyl, adamantyl, methoxy, trifluoromethoxy, phenyl, ortho-tolyl, meta-tolyl, para-tolyl, para-fluorophenyl and Si(CH₃)₃.

Examples of preferred compounds of the formula (2) are compounds (D1) to (D20) shown below.

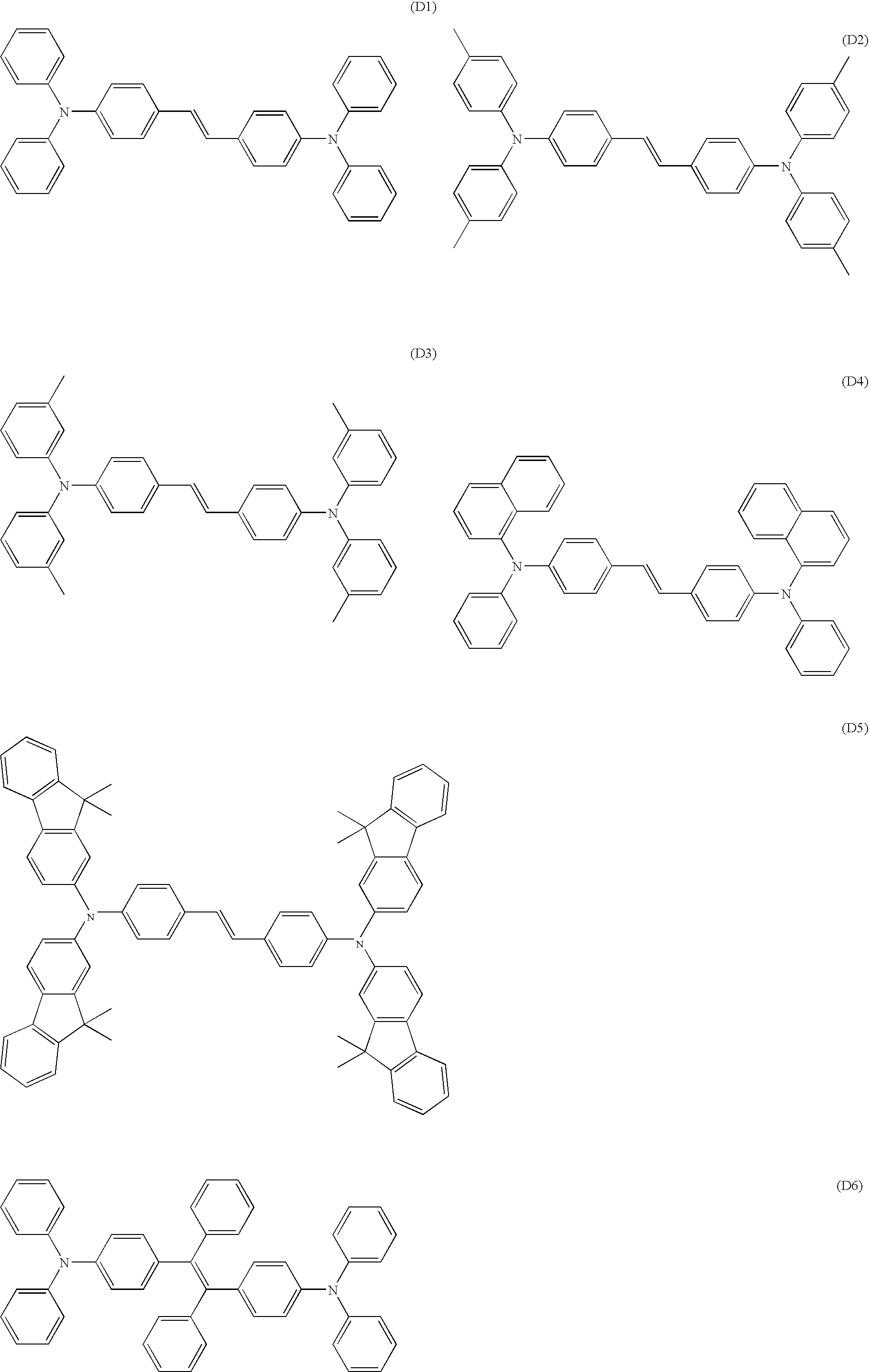

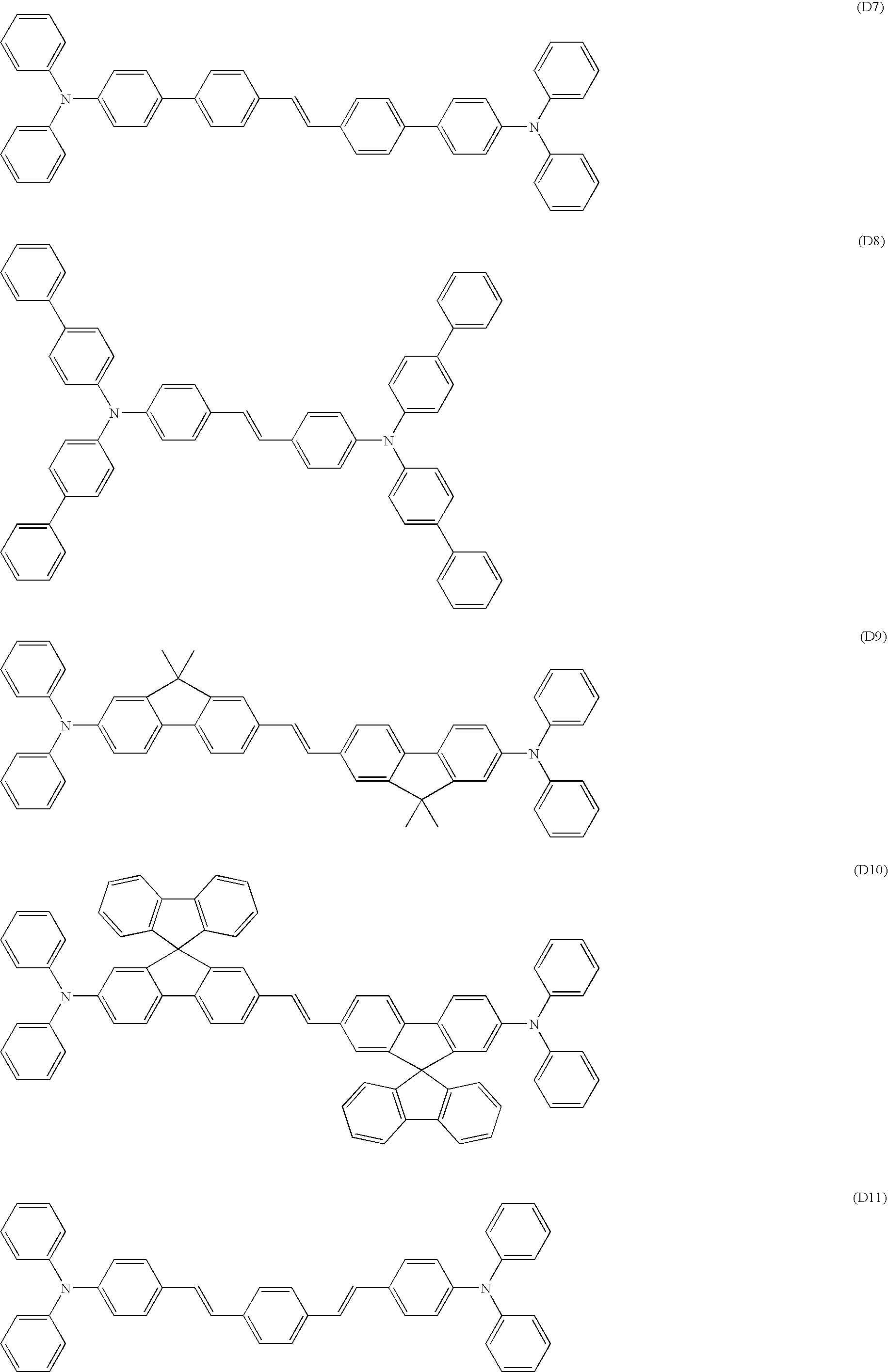

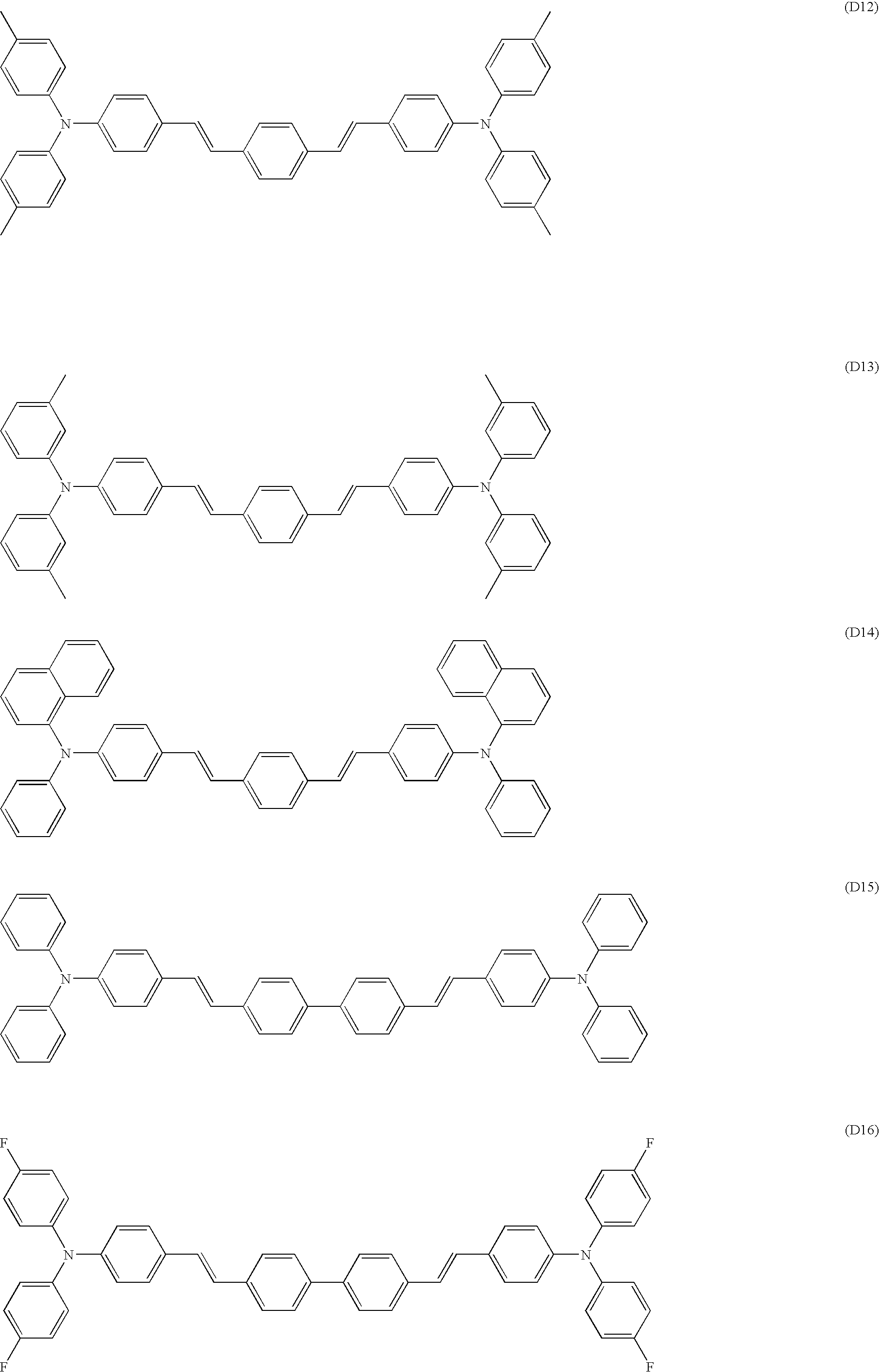

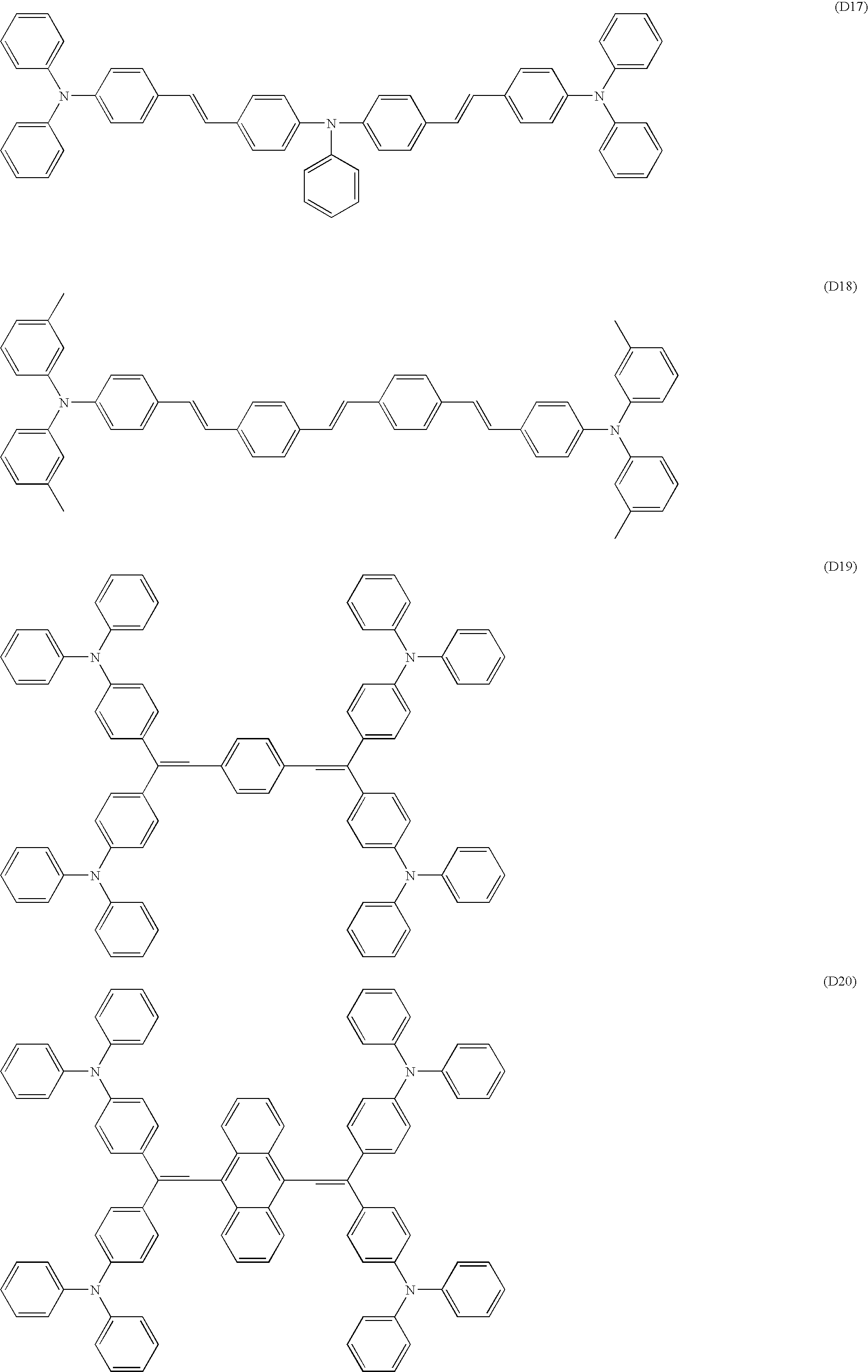

The proportion of the compound of the formula (1) in the mixture is between 1.0 and 99.9% by weight, preferably between 50.0 and 99.5% by weight, particularly preferably between 80.0 and 99.0% by weight, in particular between 90.0 and 99.0% by weight.

Correspondingly, the proportion of the compound of the formula (2) in the mixture is between 0.1 and 99.0% by weight, preferably between 0.5 and 50.0% by weight, particularly preferably between 1.0 and 20.0% by weight, in particular between 1.0 and 10.0% by weight.

Preference is furthermore given to organic electroluminescent devices, characterised in that a plurality of emitting layers are used, where at least one of these layers comprises at least one compound of the formula (1) and at least one compound of the formula (2). These emission layers particularly preferably have in total a plurality of emission maxima between 380 nm and 750 nm, overall resulting in white emission, i.e. at least one further emitting compound which can fluoresce or phosphoresce and emits yellow, orange or red light is also used in the further emitting layer(s). Particular preference is given to three-layer systems, where at least one of these layers comprises at least one compound of the formula (1) and a compound of the formula (2) and where the three layers exhibit blue, green and orange or red emission (for the basic structure, see, for example, WO 05/011013).

Apart from the compounds of the formula (1) and formula (2), further sub-stances may also be present in the emitting layer, for example hole- or electron-transport materials.

Apart from the cathode, anode and emitting layer (or emitting layers), the organic electroluminescent device may also comprise further layers. These can be, for example: hole-injection layer, hole-transport layer, electron-transport layer and/or electron-injection layer. The materials in these layers may also be doped. However, each of these layers does not necessarily have to be present. Suitable hole-transport materials are aromatic amines, as usually used in accordance with the prior art, which may also be p-doped. Suitable electron-transport materials are, for example, metal chelate complexes, for example AlQ₃, compounds based on electron-poor heterocycles, for example triazine derivatives, or compounds containing aromatic carbonyls or phosphine oxides, as described, for example, in WO 05/084081 and WO 05/084082, each of which may also be n-doped. Suitable electron-injection materials are, in particular, fluorides and oxides of the alkali metals and alkaline earth metals, for example NaF, BaF2, CaF₂, LiF or Li₂O.

Preference is furthermore given to an organic electroluminescent device, characterised in that one or more layers are coated by means of a sublimation process, in which the materials are vapour-deposited in vacuum sublimation units at a pressure below 10⁻⁵ mbar, preferably below 10⁻⁶ mbar, particularly preferably below 10⁻⁷ mbar.

Preference is likewise given to an organic electroluminescent device, characterised in that one or more layers are coated by the OVPD (organic vapour phase deposition) process or with the aid of carrier-gas sublimation. The materials are applied here at a pressure between 10⁻⁵ mbar and 1 bar.

Preference is furthermore given to an organic electroluminescent device, characterised in that one or more layers are produced from solution, such as, for example, by spin coating, or by means of any desired printing process, such as, for example, screen printing, flexographic printing or offset printing, but particularly preferably LITI (light induced thermal imaging, thermotransfer printing) or ink-jet printing. Soluble compounds of the formula (1) and formula (2) are necessary for this purpose. High solubility can be achieved either through suitable substitution of the compounds, but also through the choice of suitable atropisomers.

The invention furthermore relates to a process for the production of organic electroluminescent devices, characterised in that at least one compound of the formula (1) is applied together with at least one compound of the formula (2) by a sublimation method or from solution, for example by a printing process.

The invention furthermore relates to mixtures comprising at least one compound of the formula (1) and at least one compound of the formula (2), where the above-mentioned preferences likewise apply to the mixtures.

The invention furthermore relates to the use of the mixtures according to the invention for the production of organic electronic devices, in particular organic electroluminescent devices.

The organic electroluminescent devices according to the invention have higher stability compared with systems in accordance with the prior art, in which the emitters of the formula (2) are used in different host materials, which is particularly evident from a significantly longer lifetime.

The present application text and also the examples below are directed to the use of mixtures according to the invention in relation to OLEDs and the corresponding displays. In spite of this restriction of the description, it is possible for the person skilled in the art, without further inventive step, also to use the mixtures according to the invention for further uses in other electronic devices, for example for organic field-effect transistors (O-FETs), organic thin-film transistors (O-TFTs), organic light-emitting transistors (O-LETs), organic integrated circuits (O—ICs), organic solar cells (O—SCs), organic field-quench devices (O-FQDs), organic photoreceptors or organic laser diodes (O-lasers).

The present invention furthermore relates to the use of the mixtures according to the invention in the corresponding devices and to these devices themselves.

The invention is explained in greater detail by the following examples without wishing to restrict it thereby.

### EXAMPLES

### Example 1

### Production of OLEDs

OLEDs are produced by a general process as described in WO 04/05891 1, which is adapted in the individual case to the respective circumstances (for example layer-thickness variation in order to achieve optimum efficiency or colour). The basic structure and the materials used (apart from the emitting layer) are identical in the examples for better comparability. OLEDs having the following structure are produced analogously to the above-mentioned general process:
Hole-injection layer (HIL) 20 nm PEDOT (spin-coated from water; purchased from H. C. Starck, Goslar, Germany; poly(3,4-ethylenedioxy-2,5-thiophene))
Hole-transport layer (HTL) 10 nm 2,2′,7,7′-tetrakis(di-para-tolylamino)spiro-9,9′-bifluorene (abbreviated to HTM-1)
Hole-transport layer (HTL) 30 nm NPB (N-naphthyl-N-phenyl-4,4′-diaminobiphenyl)
Emission layer (EML) see Table 1 for materials, concentration and layer thickness
Electron conductor (ETL) 20 nm AlQ₃ (purchased from SynTec, tris(quinolinato)aluminium(III))
Cathode 1 nm LiF, 150 nm Al on top.

These OLEDs are characterised by standard methods; for this purpose, the electroluminescence spectra, the efficiency (measured in cd/A), the power efficiency (measured in Im/W) as a function of the brightness, calculated from current/voltage/brightness characteristic lines (IUL characteristic lines), and the lifetime are determined. The lifetime is defined as the time after which the initial brightness of 1000 cd/m² has dropped to half.

Table 1 shows the results for some OLEDs (Examples 2 to 9) which comprise dopant D1, where the composition of the EML including the layer thicknesses is also shown in each case.

The structure of dopant D1 is depicted below:

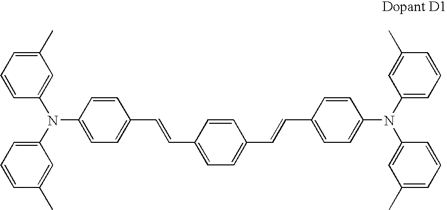

9,10-Bis(1-naphthyl)anthracene (H1) and 9,10-bis(4-methylnaphth-1-yl)anthracene (H2, synthesised as described in WO 06/048268; lower-solubility atropisomer with an atropisomer excess of 99%) are employed as host material according to the invention. Host materials H3 (9,10-bis(2-spirobifluorenyl)anthracene), H4 and H5 are employed for comparison as host materials in accordance with the prior art. The host materials are depicted below:

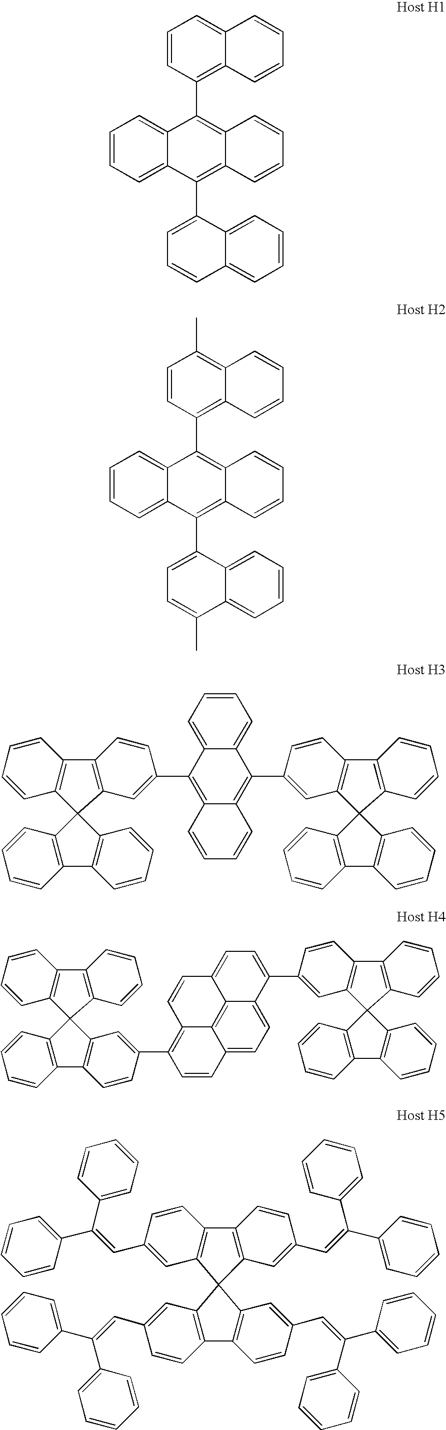

As can be seen from the examples in Table 1, the electroluminescent devices according to the invention exhibit higher efficiency and a longer lifetime for comparable colour coordinates compared with electroluminescent devices in accordance with the prior art

TABLE 1

| | | | | Max. efficiency | Voltage (V) at | | Lifetime |
|---|---|---|---|---|---|---|---|
| Example | HTL1 | HTL2 | EML | (cd/A) | 100 cd/m² | CIE | (h) |
| Example 2 | HTM-1 | NPB | H1:D1 (3%) | 11.8 | 5.5 | x = 0.17; y = 0.32 | 6700 |
| | (10 nm) | (30 nm) | (30 nm) | | | | |
| Example 3 | HTM-1 | NPB | H1:D1 (5%) | 12.2 | 5.3 | x = 0.17; y = 0.33 | 7000 |
| | (10 nm) | (30 nm) | (30 nm) | | | | |
| Example 4 | HTM-1 | NPB | H1:D1 (7%) | 11.5 | 5.2 | x = 0.18; y = 0.36 | 5300 |
| | (10 nm) | (30 nm) | (30 nm) | | | | |
| Example 5 | HTM-1 | NPB | H2:D1 (5%) | 11.9 | 5.4 | x = 0.17; y = 0.33 | 2300 |
| | (10 nm) | (30 nm) | (30 nm) | | | | |
| Example 6 | HTM-1 | NPB | H3:D1 (5%) | 5.9 | 5.8 | x = 0.18; y = 0.31 | 650 |
| (comparison) | (10 nm) | (20 nm) | (30 nm) | | | | |
| Example 7 | HTM-1 | NPB | H4:D1 (5%) | 5.4 | 6.5 | x = 0.19; y = 0.37 | 350 |
| (comparison) | (10 nm) | (30 nm) | (30 nm) | | | | |
| Example 8 | HTM-1 | NPB | H5 | 4.2 | 5.8 | x = 0.17; y = 0.26 | 400 |
| (comparison) | (10 nm) | (30 nm) | (30 nm) | | | | |
| Example 9 | HTM-1 | NPB | H5:D1 (5%) | 4.9 | 6.3 | x = 0.17; y = 0.31 | 300 |
| (comparison) | (10 nm) | (30 nm) | (30 nm) | | | | |

1-13. (canceled)

14. An organic electroluminescent device comprising an anode, a cathode, and at least one organic layer, wherein said at least one organic layer comprises:
at least one compound of formula (1) 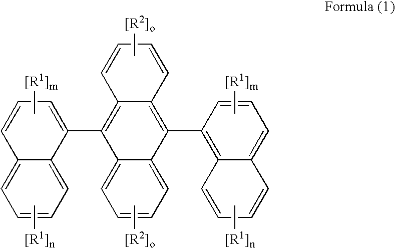
wherein
R¹ is, identically or differently on each occurrence, F; Cl; Br; I; CN; a straight-chain alkyl, alkoxy, or thioalkoxy group having up to 40 C atoms and optionally substituted by one or more radicals R³, wherein one or more non-adjacent CH₂ groups is optionally replaced by —R³C═CR³—, —C≡C—, Si(R³)₂, Ge(R³)₂, Sn(R³)₂, C═O, C═S, C═Se, C═NR², —O—, —S—, —N(R³)— or —CONR³—, and wherein one or more H atoms are optionally replaced by F, Cl, Br, I, CN, or NO₂; a branched or cyclic alkyl, alkoxy, or thioalkoxy group having 3 to 40 C atoms and optionally substituted by one or more radicals R³, wherein one or more non-adjacent CH₂ groups is optionally replaced by —R³C═CR³—, —C≡C—, Si(R³)₂, Ge(R³)₂, Sn(R³)₂, C═O, C═S, C═Se, C═NR², —O—, —S—, —N(R³)— or —CONR³—, and wherein one or more H atoms are optionally replaced by F, Cl, Br, I, CN, or NO₂; an aralkyl group having 7 to 30 C atoms and optionally substituted by one or more radicals R³; or an aryloxy or heteroaryloxy group having 5 to 24 aromatic ring atoms and optionally substituted by one or more non-aromatic radicals R³; wherein two or more substituents R¹ optionally define a mono- or polycyclic, aliphatic ring system with one another;
R² is, identically or differently on each occurrence R¹ or an aromatic or heteroaromatic ring system having 5 to 30 aromatic ring atoms and optionally substituted by one or more radicals R³;
R³ is, identically or differently on each occurrence, H or an aliphatic or aromatic hydrocarbon radical having up to 20 C atoms; wherein two or more radicals R³ optionally define a mono- or polycyclic, aliphatic, or aromatic ring system with one another;
m is, identically or differently on each occurrence, 0, 1, 2, or 3;
n and o
are, identically or differently on each occurrence, 0, 1, 2, 3, or 4; and
at least one compound of formula (2) 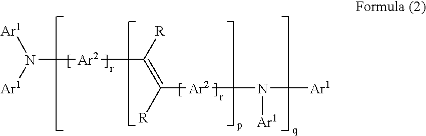
wherein
Ar¹ is, identically or differently on each occurrence, an aromatic or heteroaromatic ring system having 5 to 30 aromatic ring atoms and optionally substituted by one or more radicals R⁴;
Ar² is, identically or differently on each occurrence, an arylene or heteroarylene group having 5 to 20 aromatic ring atoms and optionally substituted by one or more radicals R⁴;
R is, identically or differently on each occurrence, H; F; CN; a straight-chain alkyl group having up to 40 C atoms and optionally substituted by one or more radicals R⁵, wherein one or more non-adjacent CH₂ groups which are not bonded directly to the double bond are optionally replaced by —R⁵C—CR⁵—, —C≡C—, Si(R⁵)₂, Ge(R⁵)₂, Sn(R⁵)₂, C═O, C═S, C═Se, C═NR⁵, —O—, —S—, —N(R⁵)—, or —CONR⁵—, and wherein one or more H atoms are optionally replaced by F, Cl, Br, I, CN, or NO₂; a branched or cyclic alkyl chain having 3 to 40 C atoms and optionally substituted by one or more radicals R⁵, wherein one or more non-adjacent CH₂ groups which are not bonded directly to the double bond are optionally replaced by —R⁵C═CR⁵—, —C≡C—, Si(R⁵)₂, Ge(R)₂, Sn(R⁵)₂, C═O, C═S, C═Se, C═NR⁵, —O—, —S—, —N(R⁵)—, or —CONR⁵—, and wherein one or more H atoms are optionally replaced by F, Cl, Br, I, CN, or NO₂; or an aryl or heteroaryl group having 5 to 30 aromatic ring atoms and optionally substituted by one or more radicals R⁵ or by a diphenylamino group, wherein the phenyl groups of said diphenylamino group are optionally substituted by non-aromatic radicals R;
R⁴ is, identically or differently on each occurrence, H; F; Cl; Br; I; CN; Si(5)₃; N(R⁵)₂; a straight-chain alkyl, alkoxy, or thioalkoxy group having up to 40 C atoms and optionally substituted by one or more radicals R⁵, wherein one or more non-adjacent CH₂ groups are optionally replaced by —R⁵C═CR⁵—, —C≡C—, Si(W⁵)₂, Ge(R⁵)₂, Sn(R⁵)₂, C═O, C═S, C═Se, C═NR⁵, —O—, —S—, —N(R⁵)—, or —CONR⁵—, and wherein one or more H atoms are optionally replaced by F, Cl, Br, I, CN, or NO₂; a branched or cyclic alkyl, alkoxy, or thioalkoxy group having 3 to 40 C atoms and optionally substituted by one or more radicals R⁵, wherein one or more non-adjacent CH₂ groups are optionally replaced by —R⁵C═CR⁵—, —C≡C—, Si(R⁵)₂, Ge(R⁵)₂, Sn(R⁵)₂, C═O, C═S, C═Se, C═NR⁵, —O—, —S—, —N(R⁵)—, or —CONR⁵—, and wherein one or more H atoms are optionally replaced by F, Cl, Br, I, CN, or NO₂; an aryl or heteroaryl group having 5 to 30 aromatic ring atoms and optionally substituted by one or more non-aromatic radicals R⁵, or an aryloxy or heteroaryloxy group having 5 to 24 aromatic ring atoms and optionally substituted by one or more non-aromatic radicals R⁴; wherein two or more substituents R⁴ optionally define a mono- or polycyclic, aliphatic or aromatic ring system with one another and/or Ar¹ and/or Ar²;
R⁵ is, identically or differently on each occurrence, H or an aliphatic or aromatic hydrocarbon radical having up to 20 C atoms; wherein two or more radicals R⁵ optionally define a mono- or polycyclic, aliphatic, or aromatic ring system with one another;
p and r
are, identically or differently on each occurrence, 1, 2, or 3;
q is 1, 2, or 3.

15. The organic electroluminescent device of claim 14, wherein R¹ is, identically or differently on each occurrence, F; a straight-chain alkyl or alkoxy group having up to 6 C atoms, wherein one or more CH₂ groups are optionally replaced by —R³C═CR³—, Si(R³)₂, —O—, —S—, or —N(R³)—, and wherein one or more H atoms are optionally replaced by F; or a branched or cyclic alkyl or alkoxy group having 3 to 10 C atoms, wherein one or more CH₂ groups are optionally replaced by —R³C═CR³—, Si(R³)₂, —O—, —S—, or —N(R³)—, and wherein one or more H atoms are optionally replaced by F; wherein two or more radicals R¹ optionally define a mono- or polycyclic, aliphatic ring system with one another.

16. The organic electroluminescent device of claim 14, wherein K is an aromatic or heteroaromatic ring system having 5 to 16 aromatic ring atoms and optionally substituted by one or more radicals R³.

17. The organic electroluminescent device of claim 14, wherein said compounds of the formula (1) are pure hydrocarbon compounds.

18. The organic electroluminescent device of claim 14, wherein Art is, identically or differently on each occurrence, an aryl, biaryl, or heteroaryl group having 6 to 14 C atoms and optionally substituted by one or more radicals R⁴.

19. The organic electroluminescent device of claim 18, wherein Art is, identically or differently on each occurrence, an aryl or biaryl group having 6 to 14 C atoms and optionally substituted by one or more radicals R⁴.

20. The organic electroluminescent device of claim 14, wherein Ar² is, identically or differently on each occurrence, an arylene or heteroarylene group having 5 to 14 aromatic ring atoms and optionally substituted by one or more radicals R⁴.

21. The organic electroluminescent device of claim 20, wherein Ar² is, identically or differently on each occurrence, an arylene group having 5 to 14 aromatic ring atoms and optionally substituted by one or more radicals R⁴.

22. The organic electroluminescent device of claim 14, wherein R is, identically or differently on each occurrence, H; a straight-chain alkyl group having 1 to 4 C atoms optionally substituted by one or more radicals R⁵; a branched or cyclic alkyl group having 3 to 5 C atoms optionally substituted by one or more radicals R⁵; or a phenyl or naphthyl group optionally substituted by one or more radicals R⁵.

23. The organic electroluminescent device of claim 14, wherein said compounds of formula (2) are selected from compounds of formula (2a): 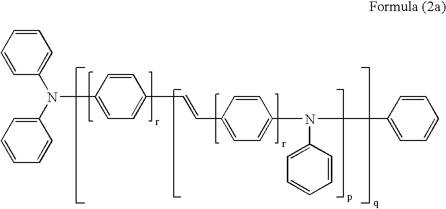
wherein the phenyl or phenylene groups are optionally substituted by one or more radicals R⁴.

24. The organic electroluminescent device of claim 14, wherein R⁴ is selected from the group consisting of H; F; straight-chain alkyl or alkoxy groups having up to 6 C atoms and optionally substituted by one or more radicals R⁵, wherein one or more CH₂ groups are optionally replaced by —R⁵C═CR⁵—, Si(R⁵)₂, —O—, —S—, or —N(R⁵)—, and wherein one or more H atoms are optionally replaced by F; a branched or cyclic alkyl or alkoxy groups having 3 to 10 C atoms and optionally substituted by one or more radicals R⁵, wherein one or more CH₂ groups are optionally replaced by —R⁵C═CR⁵—, Si(R⁵)₂, —O—, —S—, or —N(R⁵)—, and wherein one or more H atoms are optionally replaced by F; or a monovalent aryl or heteroaryl group having 5 to 14 aromatic ring atoms; wherein two or more radicals R⁴ optionally define a ring system with one another.

25. The organic electroluminescent device of claim 14, further comprising at least one additional layer selected from the group consisting of hole-injection layers, hole-transport layers, electron-transport layers, electron-injection layers, and combinations thereof, and wherein said organic electroluminescent device optionally comprises a plurality of emitting layers making it capable of emitting white light.

26. A process for producing the organic electroluminescent devices of claim 14, wherein at least one compound of formula (1) is applied together with at least one compound of formula (2) by a sublimation method or from solution, for example by a printing process.

27. A process for producing the organic electroluminescent devices of claim 14, wherein at least one compound of formula (1) is applied together with at least one compound of formula (2) by a printing process.

28. A mixture comprising at least one compound of formula (1) 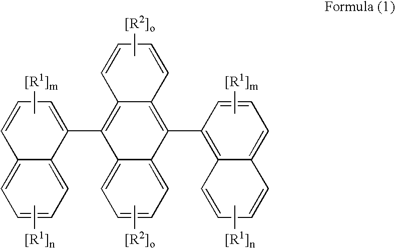
wherein
R¹ is, identically or differently on each occurrence, F; Cl; Br; I; CN; a straight-chain alkyl, alkoxy, or thioalkoxy group having up to 40 C atoms and optionally substituted by one or more radicals R³, wherein one or more non-adjacent CH₂ groups is optionally replaced by —R³C═CR³—, —C≡C—, Si(R³)₂, Ge(R³)₂, Sn(R³)₂, C═O, C═S, C═Se, C═NR², —O—, —S—, —N(R³)— or —CONR³—, and wherein one or more H atoms are optionally replaced by F, Cl, Br, I, CN, or NO₂; a branched or cyclic alkyl, alkoxy, or thioalkoxy group having 3 to 40 C atoms and optionally substituted by one or more radicals R³, wherein one or more non-adjacent CH₂ groups is optionally replaced by —R³C═CR³—, —C≡C—, Si(R³)₂, Ge(R³)₂, Sn(R³)₂, C═O, C═S, C═Se, C═NR², —O—, —S—, —N(R³)— or —CONR³—, and wherein one or more H atoms are optionally replaced by F, Cl, Br, I, CN, or NO₂; an aralkyl group having 7 to 30 C atoms and optionally substituted by one or more radicals R³; or an aryloxy or heteroaryloxy group having 5 to 24 aromatic ring atoms and optionally substituted by one or more non-aromatic radicals R³; wherein two or more substituents R¹ optionally define a mono- or polycyclic, aliphatic ring system with one another;
R² is, identically or differently on each occurrence, R¹ or an aromatic or heteroaromatic ring system having 5 to 30 aromatic ring atoms and optionally substituted by one or more radicals R³;
R³ is, identically or differently on each occurrence, H or an aliphatic or aromatic hydrocarbon radical having up to 20 C atoms; wherein two or more radicals R³ optionally define a mono- or polycyclic, aliphatic, or aromatic ring system with one another;
m is, identically or differently on each occurrence, 0, 1, 2, or 3;
n and o
are, identically or differently on each occurrence, 0, 1, 2, 3, or 4; and
at least one compound of formula (2) 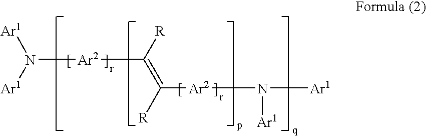
wherein
Ar¹ is, identically or differently on each occurrence, an aromatic or heteroaromatic ring system having 5 to 30 aromatic ring atoms and optionally substituted by one or more radicals R⁴;
Ar² is, identically or differently on each occurrence, an arylene or heteroarylene group having 5 to 20 aromatic ring atoms and optionally substituted by one or more radicals R⁴;
R is, identically or differently on each occurrence, H; F; CN; a straight-chain alkyl group having up to 40 C atoms and optionally substituted by one or more radicals R⁵, wherein one or more non-adjacent CH₂ groups which are not bonded directly to the double bond are optionally replaced by —R⁵C═CR⁵—, —C≡C—, Si(R⁵)₂, Ge(R⁵)₂, Sn(R⁵)₂, C═O, C═S, C═Se, C═NR⁵, —O—, —S—, —N(R⁵)—, or —CONR⁵—, and wherein one or more H atoms are optionally replaced by F, Cl, Br, I, CN, or NO₂; a branched or cyclic alkyl chain having 3 to 40 C atoms and optionally substituted by one or more radicals R⁵, wherein one or more non-adjacent CH₂ groups which are not bonded directly to the double bond are optionally replaced by —R⁵C═CR⁵—, —C≡C—, Si(R⁵)₂, Ge(R⁵)₂, Sn(R⁵)₂, C═O, C═S, C═Se, C═NR⁵, —O—, —S—, —N(R⁵)—, or —CONR⁵—, and wherein one or more H atoms are optionally replaced by F, Cl, Br, I, CN, or NO₂; or an aryl or heteroaryl group having 5 to 30 aromatic ring atoms and optionally substituted by one or more radicals R⁵ or by a diphenylamino group, wherein the phenyl groups of said diphenylamino group are optionally substituted by non-aromatic radicals R;
R⁴ is, identically or differently on each occurrence, H; F; Cl; Br; I; CN; Si(W)₃; N(R⁵)₂; a straight-chain alkyl, alkoxy, or thioalkoxy group having up to 40 C atoms and optionally substituted by one or more radicals R⁵, wherein one or more non-adjacent CH₂ groups are optionally replaced by —R⁵C═CR⁵—, —C≡C—, Si(R⁵)₂, Ge(R⁵)₂, Sn(R⁵)₂, C═O, C═S, C═Se, C═NR⁵, —O—, —S—, —N(R⁵)—, or —CONR⁵—, and wherein one or more H atoms are optionally replaced by F, Cl, Br, I, CN, or NO₂; a branched or cyclic alkyl, alkoxy, or thioalkoxy group having 3 to 40 C atoms and optionally substituted by one or more radicals R⁵, wherein one or more non-adjacent CH₂ groups are optionally replaced by —R⁵C═CR⁵—, —C≡C—, Si(R⁵)₂, Ge(R⁵)₂, Sn(R⁵)₂, C═O, C═S, C═Se, C═NR⁵, —O—, —S—, —N(R⁵)—, or —CONR⁵—, and wherein one or more H atoms are optionally replaced by F, Cl, Br, I, CN, or NO₂; an aryl or heteroaryl group having 5 to 30 aromatic ring atoms and optionally substituted by one or more non-aromatic radicals R⁵, or an aryloxy or heteroaryloxy group having 5 to 24 aromatic ring atoms and optionally substituted by one or more non-aromatic radicals R⁴; wherein two or more substituents R⁴ optionally define a mono- or polycyclic, aliphatic or aromatic ring system with one another and/or Ar¹ and/or Ar²;
R⁵ is, identically or differently on each occurrence, H or an aliphatic or aromatic hydrocarbon radical having up to 20 C atoms; wherein two or more radicals R⁵ optionally define a mono- or polycyclic, aliphatic, or aromatic ring system with one another;
p and r
are, identically or differently on each occurrence, 1, 2, or 3;
q is 1, 2, or 3.

29. An organic electroluminescent device comprising the mixture of claim 28.
